(19) United States
(12) Patent Application Publication
(10) Pub. No.: US 2016/0241231 A1
(43) Pub. Date: Aug. 18, 2016

(54) RF Switch

(71) Applicant: Infineon Technologies AG, Neubiberg (DE)

(72) Inventors: Thomas Leitner, Pregarten (AT); Johann-Peter Forstner, Steinhoering (DE); Udo Gerlach, Muenchen (DE)

(21) Appl. No.: 14/624,389

(22) Filed: Feb. 17, 2015

(51) Int. Cl. H03K 17/60

(52) U.S. Cl. CPC H03K 17/60

(57) ABSTRACT

A bipolar transistor switches for radio frequency signals are disclosed. In an embodiment a device includes a first radio frequency (RF) terminal, a second RF terminal, and a bipolar transistor, wherein an emitter terminal of the bipolar transistor is coupled to the first RF terminal, and wherein a collector terminal of the bipolar transistor is coupled to the second RF terminal. The device further includes a base current supply circuit configured to selectively supply a base current to a base terminal of the bipolar transistor.

### TECHNICAL FIELD

The present application relates to a radio frequency (RF) switch and to corresponding devices.

### BACKGROUND

Radio frequency (RF) switches are used to selectively open and close electrical connections used for radio frequency signals, sometimes also referred to as high frequency signals. Such radio frequency signals, for example, in mobile communication applications, may have frequencies exceeding 100 MHz, for example, in a range between 600 MHz and 5 GHz.

As RF switches, in many applications field effect transistors (FETs) are used. Also, PIN diodes are sometimes used. For various reasons, it may be desirable to also use bipolar junction transistors (BJTs) as RF switches. Previous approaches, for example, used a base emitter or base collector coupling for such a bipolar transistor based switch, i.e., an RF signal source and an RF signal destination to be selectively coupled via the switch were coupled to base and emitter or base and collector of a BJT, respectively. However, at least in some applications such a coupling via a base emitter diode or a base collector diode of a BJT may have a comparatively high damping and/or a comparatively low linearity.

### SUMMARY

In the following, various embodiments will be described in detail referring to the attached drawings. It is to be noted that these embodiments serve illustrative purposes only and are not to be taken in a limiting sense. For example, while embodiments may be described as comprising a plurality of features or elements, in other embodiments some of these features or elements may be omitted, and/or may be replaced by alternative features or elements. In yet other embodiments, additional features or elements in addition to the ones explicitly described herein or shown in the drawings may be provided. Furthermore, features or elements from different embodiments may be combined to form further embodiments. Variations and modifications discussed with respect to one of the embodiments may also be applicable to other embodiments.

Any direct connection or coupling between elements or components shown in the drawings or described herein, i.e., a connection or coupling without intervening elements, may also be implemented by an indirect connection or coupling, i.e., a connection or coupling comprising one or more additional intervening elements, and vice versa, as long as the general function and/or purpose of the connection or coupling, for example, to transmit a certain kind of signal or to transmit a certain kind of information, is essentially maintained. Any directional references made when describing the figures like “left”, “right” etc. are given merely for ease of reference to various parts of the figures and is not to be construed as implying any particular spatial arrangement of the elements or components described.

In some embodiments, a collector-emitter coupling of a bipolar junction transistor (BJT) is used for switching radio frequency (RF) signals, for example, RF signals having a frequency exceeding 100 MHz, for example, between 600 MHz and 5 GHz.

In some embodiments, a closing and opening of the switch may be controlled by supplying a base current to a base terminal of the bipolar junction transistor.

In some embodiments, capacitances may be coupled to the collector and emitter terminals to block direct current (DC) components.

In some embodiments, the BJT may be operated in a forward reverse saturation region.

Generally, a BJT in the context of the present application may be described as “open” or “off” when it is essentially non-conducting between its collector and emitter terminals, and may be described as “closed” or “on” when it is conducting RF signals between its collector and emitter terminals.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a block diagram illustrating a device according to an embodiment;

FIG. 2 is a diagram illustrating a bipolar junction transistor usable in embodiments;

FIGS. 3 and 4 show characteristic curves for bipolar junction transistors to illustrate operation of some embodiments;

FIG. 5 illustrates a small signal equivalent circuit of a bipolar junction transistor in an off state;

FIG. 6 illustrates a small signal equivalent circuit of a bipolar junction transistor in an on state;

FIG. 7 illustrates a circuit diagram of a device according to an embodiment;

FIG. 8 illustrates a circuit diagram of a device according to an embodiment;

FIG. 9 illustrates a circuit diagram of a device according to an embodiment;

FIG. 10 illustrates a circuit diagram of a device according to an embodiment; and

FIG. 11 illustrates a circuit diagram of a device according to an embodiment.

### DETAILED DESCRIPTION OF ILLUSTRATIVE EMBODIMENTS

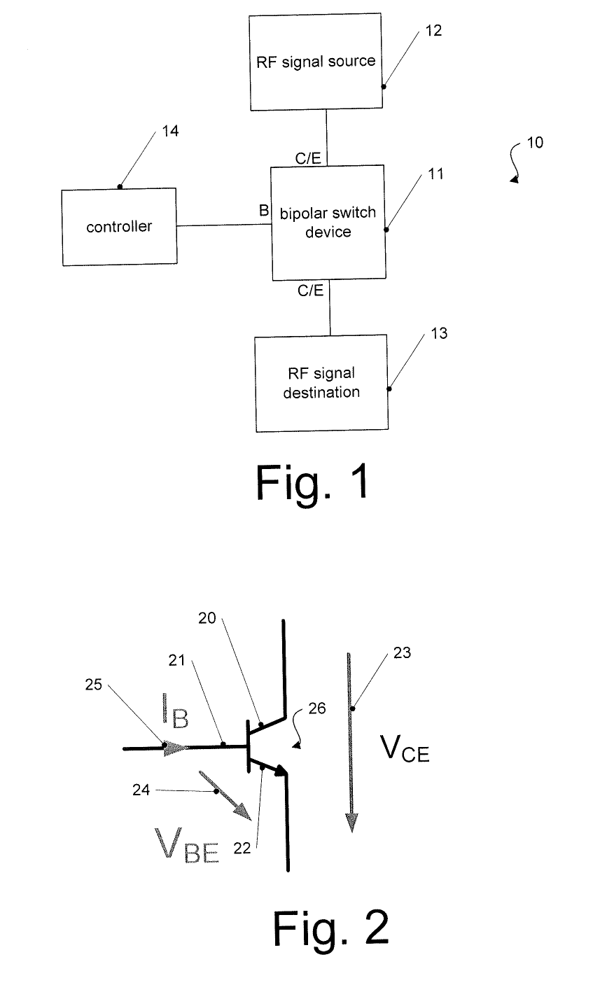

Turning now to the figures, FIG. 1 illustrates a device according to an embodiment. The device 10 of FIG. 1 comprises a bipolar switch device 11, the bipolar switch device comprising a bipolar junction transistor (BJT) and optionally additional elements like capacitors or resistors coupled to the BJT.

An RF signal source 12 is coupled to one of a collector (C) or emitter (E) terminal of the BJT of bipolar switch device 11, and an RF signal destination 13 is coupled to the other one of collector and emitter of the BJT of bipolar switch device 11. RF signal source 12 may be any kind of circuit generating an RF signal. By selectively opening and closing bipolar switch device 11 and in particular the BJT thereof, the RF signal may be selectively provided to RF signal destination 13. RF signal destination 13 may, for example, be a circuit receiving the RF signal, but may also be, for example, a fixed potential like ground. In the latter case, bipolar switch device 11 may serve to selectively shunt the RF signal to ground, just to give an example.

Bipolar switch device 11 is controlled by a controller 14. In embodiments, controller 14 may serve as a base current supply circuit to selectively provide a base current to a base terminal (B) of the BJT of bipolar switch device 11. In some embodiments, as will be explained later using examples, for enabling flowing of the base current an emitter terminal of the BJT of bipolar switch device 11 may be coupled to a reference potential like ground via a resistor or another impedance.

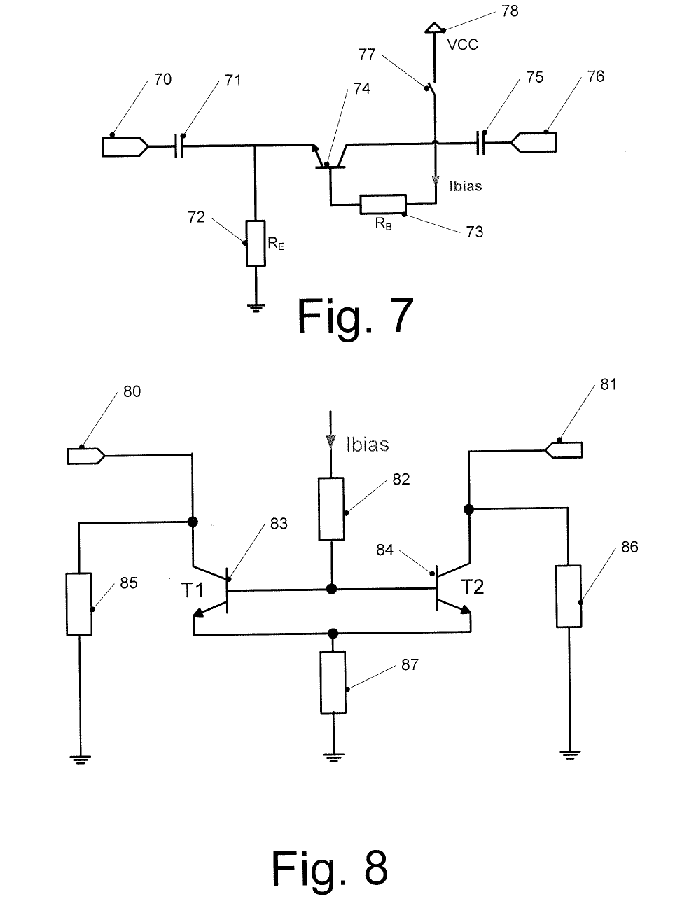

Example implementations of bipolar switch device 11 usable in some embodiments will be discussed later with reference to FIGS. 7-11. For a better understanding, before describing various example implementations in detail, with reference to FIGS. 2-6 various properties of bipolar junction transistors usable in embodiments will be explained.

FIG. 2 illustrates a bipolar junction transistor (BJT) 26 used for illustration of various features of various embodiments later. The bipolar junction transistor 26 in the example represented in FIG. 2 is an NPN transistor. However, concepts and techniques disclosed herein may also be applied to PNP transistors. NPN and PNP may also be referred to as polarities of the transition.

BJT 26 in the embodiment of FIG. 2 comprises a collector terminal 20, a base terminal 21 and an emitter terminal 22. An arrow 23 represents a collector-emitter voltage V_{CE}, an arrow 25 represents a base-emitter voltage V_{BE} and an arrow 25 represents a base current I_{B}. Voltages V_{CE}, V_{BE} and base current I_{B} will be used later for explanatory purposes.

In some embodiments, to be used as an RF switch a bipolar transistor like the bipolar transistor shown in FIG. 2 is operated in a forward saturation range or reverse saturation range. In some embodiments, a current consumption in the reverse saturation range may be lower than in the forward saturation range. To improve understanding of the embodiments described later, these modes of operation will be discussed later.

As already mentioned, embodiments use a collector-emitter coupling for switching, for example, as illustrated in FIG. 1, where an RF signal source is coupled to one of a collector terminal or emitter terminal, and an RF signal destination is coupled to the other one of collector terminal and emitter terminal. A base current may be used to control the coupling, for example, to open and close the switch. In embodiments, using such a collector-emitter coupling may enable a realization of a highly linear and/or low loss switch in bipolar technology.

In embodiments, an emitter terminal of a BJT used (for example, emitter terminal 22 of FIG. 2) may be coupled with a reference potential (for example, ground) via a resistor. Optionally, such a coupling to a reference potential may also be made for the collector terminal. In other embodiments, a coupling may be made to another blocking impedance like an external blocking coil. An RF signal may be coupled to collector and/or emitter terminals via capacitances blocking DC components. In such a case, the above-mentioned coupling of the emitter to a reference potential may enable the base current to flow via the base to the reference potential. Depending on a base current I_{B} used, the BJT (for example, BJT 26) may be set to a forward or reverse saturation mode of operation. An operating point in this respect may depend on external circuitry coupled to the bipolar transistor. For example, in a case where the collector is not coupled to further circuitry, for example, a forward saturation mode of operation may be obtained. In case the collector is coupled to further circuitry, a reverse saturation mode of operation may be obtained where base emitter and base collector diodes are forward biased diodes and a negative collector current results.

BJT 26 may be implemented based on silicon, but may be also implemented based on other materials and/or using heterostructures, for example, heterostructures comprising at least two materials selected from the group of Si, SiGe, SiC, and SiGeC. BJT 26 may, for example, be implemented as a heterojunction bipolar transistor (HBT).

A low ohmic connection between collector and emitter terminals of a BJT in a reverse saturation mode of operation, i.e., a closing of the switch, may be realized as follows:

A certain base current I_{B} is provided to the base-emitter diode of the transistor (for example, transistor 26). This base current results from an injection of minority carriers, i.e., of holes injected from base to emitter and from electrons injected from emitter to base. Such a base current may, for example, be caused by applying a certain base-emitter voltage V_{BE}, as indicated by arrow 24 of FIG. 2. In embodiments, a base region of the transistor (for example, in case of a HBT) is so thin that the injected electrons may diffuse to a space charge region of a collector-base diode before recombining in the base.

In a scenario as described above, as an operating point a collector-emitter voltage V_{CE} is established, which in embodiments may be smaller than 10 mV. In the situation described so far, a collector current does not necessarily flow. However, in reverse operation a direct current smaller than 0 occurs.

In the use as an RF switch as an embodiment, when, for example, an alternating current (AC) signal (for example, an RF signal) is applied to the collector (for example, collector terminal 20 of FIG. 2), because of the potential difference between collector and emitter electrons are provided from a collector-base space charge region to the collector. Due to this, the emitter follows the collector potential. In a reverse situation, an AC signal at the emitter leads to a collector potential (voltage) following this RC signal. Therefore, AC signals like RF signals may be transmitted from collector to emitter and vice versa.

The base current I_{B} which is a DC current, determines the properties of the collector-emitter coupling. The more the transistor is operated in saturation (irrespective of forward- or reverse operation), the more low ohmic is the collector-emitter coupling.

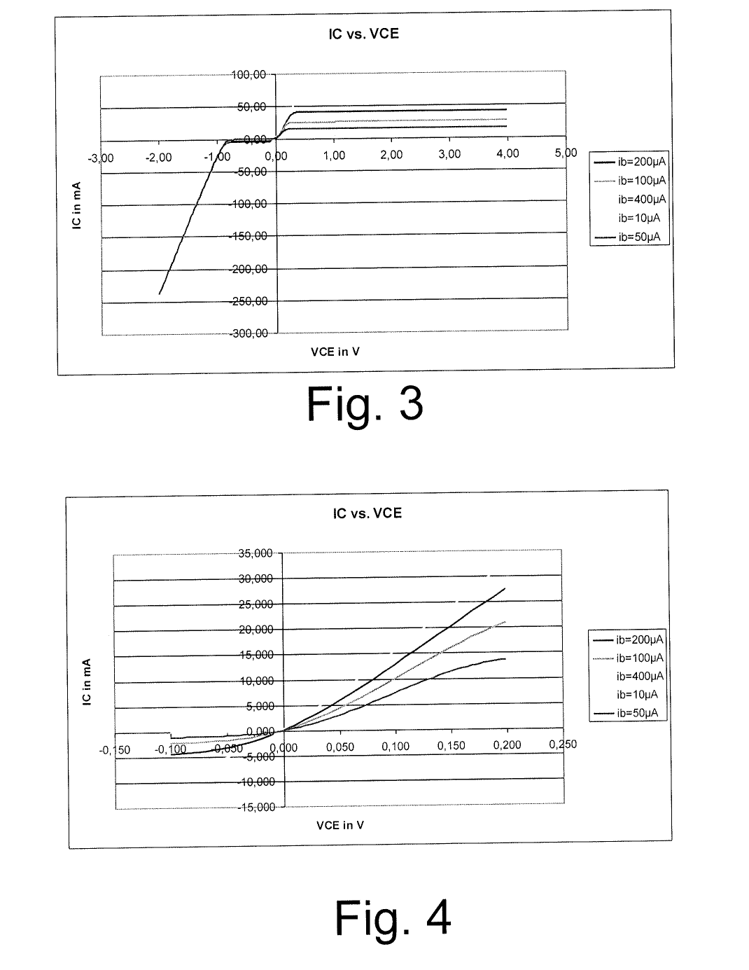

To illustrate this behavior further, FIGS. 3 and 4 show characteristic curves of a heterojunction bipolar transistor usable in embodiments. FIGS. 3 and 4 illustrate an collector current I_{C} in mA versus a collector-emitter voltage V_{CE} in V for different base currents ranging from 50 μA to 200 μA. FIG. 4 shows an enlarged view of a part of FIG. 3, in particular a part around 0 V/0 A.

As can be seen, a higher base current leads to a lower ohmic collector-emitter coupling (higher current I_{C} for the same voltage V_{CE}). The behavior in forward saturation may be seen in the first quadrant (positive V_{CE}, positive I_{C}); saturation starts at between about 0.2 V and 0.5 V, depending on the base current. Reverse saturation may be seen between about −0.1 V and −0.7 V, before the onset of reverse breakthrough.

In summary, both modes of operation (forward saturation and reverse saturation) which may be used in embodiments may be described as follows: A base emitter and a base collector diode are operated in forward bias, and between collector and emitter there is a low ohmic coupling.

In many applications, a collector-emitter voltage (V_{CE}) may be small, for example, smaller 10 mV. In such a case, for simplification purposes as an approximation a parallel coupling of the base-collector diode and base-emitter diode for reverse saturation mode may be assumed.

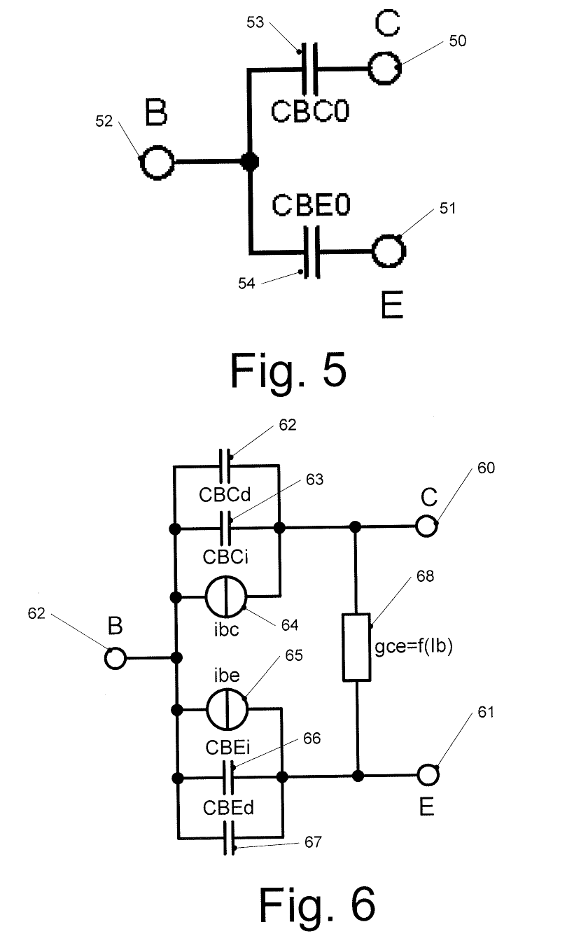

To illustrate this further, FIGS. 5 and 6 illustrate small signal equivalent circuits of bipolar junction transistors like heterojunction bipolar transistors usable in some embodiments.

FIG. 5 illustrates a small signal equivalent circuit for an off state (open state) of the transistor. In this case, only depletion layer capacitances 53 and 54 of the base-collector diode and the base-emitter diode, respectively, are essentially to be taken into account. Numeral 50 designates a collector terminal, numeral 51 designates an emitter terminal and numeral 52 designates a base terminal of the transistor. In many applications, a capacitance CBC0 of capacitance 53 representing the base collector diode is smaller than a capacitance CBE0 of the base emitter diode 54. For good isolation properties in the off state for RF applications, a low capacitance is desirable. Therefore, in embodiments the base collector diode and its capacitance 53 predominantly contribute to the isolation properties in the off state in embodiments.

FIG. 6 illustrates a small signal equivalent circuit for a bipolar junction transistor in an on state (closed state). 60 designates a collector terminal, 61 designates an emitter terminal and 62 designates a base terminal.

A base-collector diode in a closed state is represented by a non-linear diffusion capacitor 62 (CBCd), a depletion layer capacitor 63 (CBCi) and a non-linear current source 64 (ibc). Similarly, a base-emitter diode is represented by a non-linear diffusion capacitor 67 (CBEd), a depletion layer capacitor 66 (CBEi) and a non-linear current source 65 (ibe). Furthermore, the equivalent circuit of FIG. 6 comprises a resistor 68 coupled between collector terminal 60 and emitter terminal 61. A conductance value gce of resistor 68 is a function of the base current I_{b}, as can be seen from FIGS. 3 and 4.

In forward saturation, essentially only the base emitter diode is active. In reverse saturation, both diodes are active.

For example, based on the small signal equivalent circuit of FIGS. 5 and 6, in some embodiments a highly linear switch for RF signals may be realized which has low losses. Such a switch may, for example, be adapted to RF signals having comparatively low power. In such embodiments, a collector-emitter path of a bipolar junction transistor is used for a selective coupling, for example, as illustrated with reference to FIG. 1. The small signal circuit of FIG. 6 also illustrates the operation of the collector-emitter coupling, e.g., that a signal at emitter terminal 61 follows a signal at collector terminal 60 and vice versa (e.g., due to resistor 68).

The collector terminal of such a transistor in embodiments may be coupled to a remaining circuit at a location where the remaining circuit is least loaded. When the transistor is switched off, referring to FIG. 5, for example, only capacitor 53 acts as a load to the remaining circuit, capacitor 53 as explained having a lower capacitance in embodiments than capacitor 54. This may, for example, reduce an overall load on the circuit.

FIG. 7 illustrates a circuit diagram of a switch device according to an embodiment. The switch device of FIG. 7 comprises a first terminal 70 and a second terminal 76. The switch device of FIG. 7 is adapted to selectively provide a radio frequency coupling between terminals 70, 76 (i.e., to selectively provide either a low ohmic path for radio frequency signals or a high ohmic, essentially isolating, path for radio frequency signals). To provide such a switching, the switch device of FIG. 7 comprises a bipolar junction transistor 74, for example, a heterojunction bipolar transistor. An emitter terminal of transistor 74 is coupled to terminal 70 via a capacitor 71, and a collector terminal of transistor 74 is coupled to terminal 76 via a capacitor 75. Capacitors 71, 75 serve to block, for example, DC components of signals at terminal 70 or 76. Therefore, in a DC case transistor 74 is essentially floating between terminals 70, 76 and receives only AC signals, in particular RF signals, from terminal 70 or terminal 76.

Furthermore, the emitter terminal of transistor 74 is coupled to ground via a resistor 72. A base terminal of transistor 74 is coupled to a positive supply voltage 78 via a resistor 73 and a switch 77. Resistor 73 and switch 77 are examples of a base current supply circuit. When switch 77 is closed, a base current Ibias flows setting the transistor 74 to an on state (closed state), thus enabling the transmission of RF signals from terminal 70 to terminal 76 or vice versa. When switch 77 is open, no base current flows, which effectively decouples terminal 70 from terminal 76.

Resistors 73, 72 may set an operation point, in particular may determine a magnitude of a base current. Furthermore, resistors 72, 73 serve as blocking resistors that prevent that a significant portion of the RF signal is coupled to ground, thus keeping losses of the switch low in embodiments. A resistance value of resistor 72, 73 each may be 50Ω or more, but is not limited thereto.

In addition to the resistors shown, in further embodiments, also a further resistor coupling a collector terminal of transistor 74 to ground may be provided. In other embodiments, instead of one or more of the resistors, other impedances like a blocking inductivity may be used.

A magnitude of the base current Ibias of FIG. 7 may be 5 mA or less, for example, 100 μA or less, but is not limited thereto. While FIG. 7 shows a switch device using an NPN transistor 74, in other embodiments a PNP transistor may be used, for example, by reversing the polarities involved.

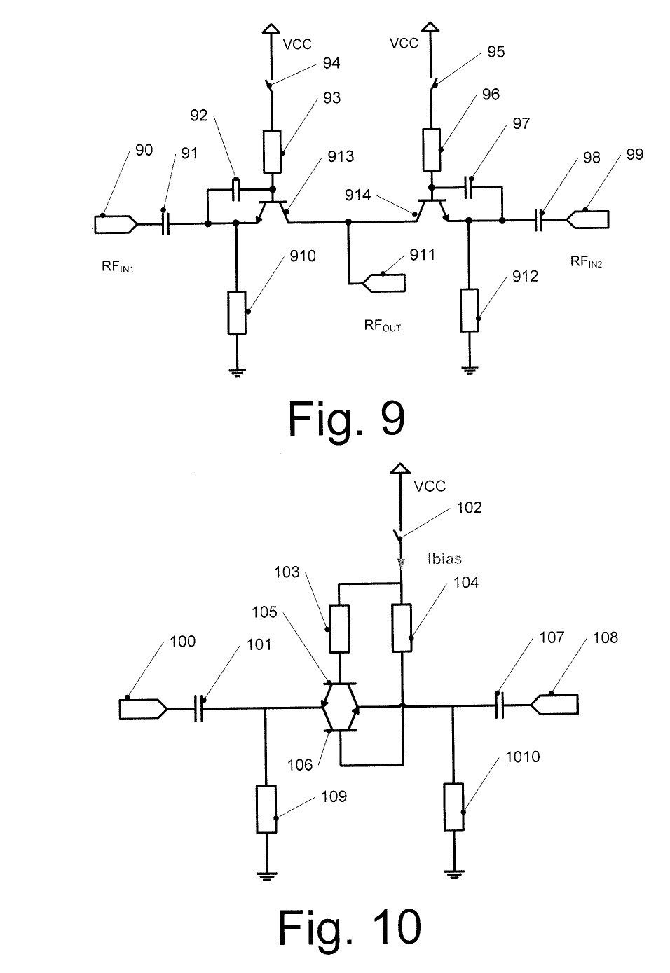

In some embodiments, to improve transmission behavior of the switch device, a capacitive base-emitter coupling may be used. An example for such a capacitive base-emitter coupling will be illustrated later with respect to FIG. 9.

Further elements which are not explicitly shown in FIG. 7 may also be used, for example, a biasing or clamping to increase the isolation in an off state of the switch device.

Next, with reference to FIGS. 8-11, further switch devices will be used, which at least in part have additional elements or features compared to the embodiment of FIG. 7.

FIG. 8 illustrates a switch device according to a further embodiment which may, for example, be used as a bypass switch. A bypass switch is generally to be understood as a switch which selectively couples two nodes of a circuit, thus bypassing circuitry provided between the two nodes when the switch is closed.

The switch device of FIG. 8 comprises a first terminal 80 and a second terminal 81 which by means of the switch device are selectively coupled with each other. As switching elements, the switch device of FIG. 8 comprises two bipolar transistors 83, 84. Base terminals of transistors 83, 84 may be provided a base current Ibias via a resistor 82, resistor 82 having essentially the same function as resistor 73 of FIG. 7. A collector terminal of transistor 83 is coupled with terminal 80, and a collector terminal of transistor 84 is coupled with terminal 81. Emitter terminals of transistors 83, 84 are coupled with each other. Furthermore, the emitter terminals of transistors 83, 84 are coupled to ground via a resistor 87, which essentially has the same function as resistor 72 of FIG. 7.

Furthermore, collector terminal of transistor 83 is coupled to ground via a resistor 85, and the collector terminal of transistor 84 is coupled to ground via a resistor 86. Resistors 85, 86 may be dimensioned similar to resistor 87 and serve for adjusting a point of operation and as blocking resistors, similar as explained for resistors 72, 73 of FIG. 8.

By providing two transistors 83, 84, a damping introduced by the switch device may be increased compared to a case where one transition is used. On the other hand, by providing two transistors 83, 84 with a coupling as shown, in some embodiments a linearity may be increased. For example, some bipolar transistors like heterojunction bipolar transistors may have an asymmetric structure, thus leading to different transfer behavior from collector to emitter and from emitter to collector. With a coupling as illustrated in FIG. 8, symmetry is increased. Furthermore, in some embodiments, by coupling collector terminals of transistors 82, 84, to terminals 80, 81, a load to a circuit connected to the switch device may be decreased, as explained before a capacitance of the base-collector diode in an off state may be lower than a capacitance of a base-emitter diode.

While not explicitly shown in FIG. 8, similar to the embodiment of FIG. 7 capacitors may be provided between terminal 80 and the collector terminal of transistor 83 and/or between terminal 81 and the collector terminal of transistor 84.

FIG. 9 illustrates a further embodiment of a switch device. The switch device of FIG. 9 comprises two input terminals 90, 99 and an output terminal 911. Via bipolar transistors 913, 914, input terminals 90, 99 may selectively be coupled to output terminal 911 for transmitting RF signals.

An emitter terminal of transistor 913 is coupled to terminal 90 via a capacitor 91, capacitor 91 serving to block DC components (similar to capacitors 71, 75 of FIG. 7). An emitter terminal of transistor 914 is coupled to terminal 99 via a capacitor 98, also to block DC components. Collector terminals of transistors 913, 914 are coupled to output terminal 911.

A base terminal of transistor 913 is coupled to a supply voltage VCC via a resistor 93 and a switch 94, which have the same function as resistor 73 and switch 77, respectively, of FIG. 7, i.e., to selectively supply a base current to transistor 913 to switch transistor 913 on and off. Likewise, a base terminal of transistor 914 is coupled to a supply voltage VCC via a resistor 96 and a switch 95 to selectively supply a base current to transistor 914, to selectively switch transistor 914 on and off.

Furthermore, the emitter terminal of transistor 913 is coupled to ground via a resistor 910, and the emitter terminal of transistor 914 is coupled to ground via a resistor 912. Resistors 910, 912 essentially serve the same function as already explained for resistor 72 of FIG. 7 and may be dimensioned in a similar manner, for example, they have a resistance value greater than 50Ω Optionally (not shown in FIG. 9) the collector terminals of transistors 913, 914 may be coupled to ground via a further resistor (like resistors 85, 86 of FIG. 8).

Additionally, in the embodiment of FIG. 9, the base terminal and emitter terminal of transistor 913 are coupled by a capacitor 92, and the base terminal and the emitter terminal of transistor 914 are coupled via a capacitor 97. Capacitors 92, 97 in some embodiments may serve to optimize a transmission behavior of the respective transistor, for example, to reduce a non-linearity. In particular, capacitors 92, 97 may improve a large signal behavior of the switch device. In other embodiments, capacitors 92, 97 may be omitted.

FIG. 10 illustrates a further embodiment of a switch device. The switch device of FIG. 10 selectively provides a coupling between terminals 100, 108. As switching elements, two bipolar transistors 105, 106 having an anti-parallel coupling as shown are provided. An emitter terminal of transistor 105 and a collector terminal of transistor 106 are coupled to terminal 100 via a capacitor 101, and a collector terminal of transistor 105 and an emitter terminal of transistor 106 are coupled to terminal 108 via a capacitor 107. Capacitors 101, 107 serve to block DC components, similar to capacitors 71, 75 of FIG. 7.

Moreover, the emitter terminal of transistor 105 and the collector terminal of transistor 106 are coupled to ground via a resistor 109, and the collector terminal of transistor 105 and the emitter terminal of transistor 106 are coupled to ground via a resistor 1010. Resistors 109, 1010 essentially serve the same function as resistor 72 of FIG. 7 and may have a resistance value exceeding 100Ω.

A base terminal of transistor 105 is coupled to a supply voltage VCC via a resistor 103 and a switch 102, and a base terminal of transistor 106 is coupled to the positive supply voltage VCC via a resistor 104 and switch 102.

By closing switch 102, transistors 105, 106 are supplied with a base current Ibias via resistors 103, 104, respectively, thus switching transistors 105, 106 on. Resistors 103, 104 essentially serve the same function as resistor 73 of FIG. 7. While two resistors 103, 104 are shown in FIG. 10, in other embodiments transistors 105, 106 may receive a bias current via the same resistor.

By providing two transistors 105, 106 with an anti-parallel coupling as illustrated in FIG. 10, in embodiments a large signal behavior and a symmetry may be improved, as essentially each of the transistors is “responsible” for transmission of a half wave. For example, by providing two transistors in case of asymmetrically implemented transistors (like some HBTs) such an asymmetry may be compensated.

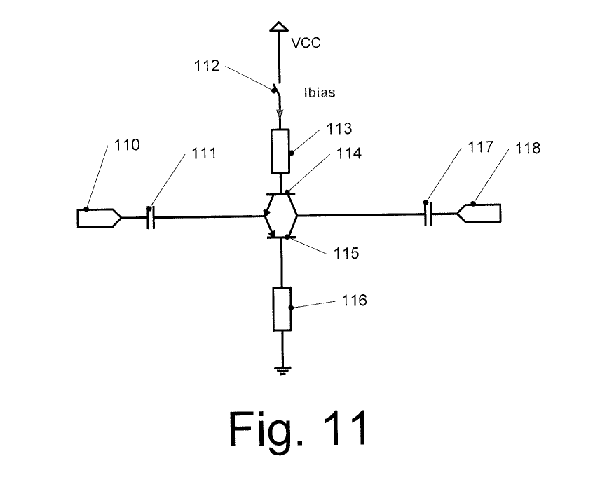

FIG. 11 illustrates a switch device usable as a transfer gate. The embodiment of FIG. 11 comprises a first terminal 110 and a second terminal 118. As switching elements, an NPN bipolar junction transistor 114 and a PNP bipolar junction transistor 115 are provided. Emitter terminals of transistors 114, 115 are coupled to terminal 110 via a capacitor 111. Collector terminals of transistors 114, 115 are coupled to terminal 118 via a capacitor 117. Capacitors 111, 117 may serve to block DC components.

Furthermore, a base terminal of transistor 114 is coupled to a positive supply voltage VCC via a resistor 113 and a switch 112. A base terminal of transistor 115 is coupled to ground via a resistor 116. When switch 112 is closed, a base current Ibias flows via resistor 113 to the base terminal of NPN transistor 114 and from the base terminal of resistor 115 via resistor 116 to ground, thus switching transistors 114, 115 to an on state, enabling RF signal transmission from terminal 110 to terminal 118 and vice versa.

It should be noted that depending on a transfer frequency of PNP transistor 115, an operating frequency of the device of FIG. 11 may be limited. The embodiment of FIG. 11 may have a good large signal behavior, for example, high linearity. Transistors 114, 115 may be implemented by stacking the two transistors, which, for example, may lead to a stacking of two base emitter diodes.

In view of the many variations and modifications of switch device described above, it is apparent that the techniques disclosed herein are not limited to any particular embodiment, and the embodiments illustrated are given by way of example only.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A device comprising:
a first radio frequency (RF) terminal;
a second RF terminal;
a bipolar transistor, wherein an emitter terminal of the bipolar transistor is coupled to the first RF terminal, and wherein a collector terminal of the bipolar transistor is coupled to the second RF terminal; and
a base current supply circuit configured to selectively supply a base current to a base terminal of the bipolar transistor.

2. The device of claim 1, wherein the bipolar transistor is configured to operate in one of a forward saturation or a reverse saturation when the base current supply circuit supplies a base current.

3. The device of claim 1, further comprising a capacitor coupled between the first RF terminal and the emitter terminal or a capacitor coupled between the second RF terminal and the collector terminal.

4. The device of claim 1, wherein the base current supply circuit comprises a switch and a resistor coupled in series between a supply voltage and the base terminal.

5. The device of claim 1, further comprising an impedance coupled between the emitter terminal of the bipolar transistor and a reference potential.

6. The device of claim 5, wherein the impedance comprises a resistor having a resistance value of at least 50Ω.

7. The device of claim 5, wherein the reference potential is ground.

8. The device of claim 1, further comprising an impedance coupled between the collector terminal of the transistor and a reference potential.

9. The device of claim 1, further comprising a capacitor coupled between the base terminal of the transistor and the emitter terminal of the transistor.

10. The device of claim 1, further comprising a further bipolar transistor coupled between the first RF terminal and the second RF terminal.

11. The device of claim 10, wherein the further transistor is coupled in series to the transistor.

12. The device of claim 11, wherein an emitter terminal of the transistor is coupled to an emitter terminal of the further transistor.

13. The device of claim 11, wherein the collector terminal of the transistor is coupled to a collector terminal of the further transistor, wherein the first and second RF terminals are input terminals, wherein an RF output terminal is coupled to a node between the collector terminal of the transistor and the collector terminal of the further transistor.

14. The device of claim 10, wherein the further transistor is coupled in parallel to the transistor.

15. The device of claim 14, wherein the collector terminal of the transistor is coupled to an emitter terminal of the further transistor, and wherein the emitter terminal of the transistor is coupled to a collector terminal of the further transistor.

16. The device of claim 14, wherein one of the transistor and the further transistor is an NPN transistor, and wherein the other one of the transistor and the further transistor is a PNP transistor, wherein the emitter terminal of the transistor is coupled to an emitter terminal of the further transistor, and wherein the collector terminal of the transistor is coupled to a collector terminal of the further transistor.

17. A radio frequency (RF) switch device comprising:
a first terminal;
a second terminal;
a bipolar transistor, wherein an emitter terminal of the bipolar transistor is coupled to the first terminal and a collector terminal of the bipolar transistor being coupled to the second terminal;
a first capacitor coupled between the emitter terminal and the first terminal;
a second capacitor coupled between the collector terminal and the second terminal;
an impedance coupled between the emitter terminal and ground; and
a switch coupled between a base terminal of the bipolar transistor and a positive supply voltage.

18. The device of claim 17, further comprising a resistor coupled between the base terminal and the positive supply voltage.

19. The device of claim 17, further comprising a further bipolar transistor coupled to the bipolar transistor in series or in parallel.

20. The device of claim 17, further comprising a capacitor coupled between the base terminal and the emitter terminal.
